(19) United States
(12) Patent Application Publication
(10) Pub. No.: US 2005/0017238 A1
(43) Pub. Date: Jan. 27, 2005

(54) Forming a high dielectric constant film using metallic precursor

(76) Inventors: Justin K. Brask, Portland, OR (US); Mark L. Doczy, Beaverton, OR (US); John P. Barnak, Portland, OR (US)

Correspondence Address: Timothy N. Trop;TROP. PRUNER & HU, P.C., STE 100, 8554 KATY FWY, HOUSTON, TX, 77024-1841, US

(21) Appl. No.: 10/626,336

(22) Filed: Jul. 24, 2003

(51) Int. Cl. H01L 29/12

(52) U.S. Cl. 257/43

(57) ABSTRACT

A liquid form oxidizer may be utilized to form a high dielectric constant dielectric material from a metallic precursor for semiconductor applications. The use of a liquid rather than a gaseous oxidizer reduces the presence of an oxidation under layer under the metallic precursor. It may also, in some embodiments, result in a purer dielectric film.

### BACKGROUND

This invention relates generally to semiconductor processes that use high dielectric constant films and, particularly, to those that use metallic precursors for forming such films.

In a number of different cases, it is highly desirable to have a dielectric film with a high dielectric constant. One way to form such films is to deposit a metallic precursor material, such as aluminum. That precursor material may then be oxidized to form a high dielectric constant oxide.

One problem with this approach is that the oxidation of the metallic precursor not only oxidizes the film itself, but also penetrates into the underlying substrate below the film to form undesirable dielectric under layers with little or no controllability.

Thus, since controllability is an important part of any semiconductor process, it may be undesirable to form other dielectric layers separate from the desired high dielectric constant film. The ultra-thin dielectric layers formed by conventional processes may have a relatively high impurity count and low oxygen content. As a result, these films may need to be cleaned and re-oxidized in some cases. This cleaning or re-oxidizing produces even more uncontrollability, making the process disadvantageous.

Thus, there is a need for alternate ways to form very thin high dielectric constant films.

### BRIEF DESCRIPTION OF THE DRAWINGS

FIG. 1 is a depiction of one embodiment of the present invention; and

FIG. 2 is a depiction of a second stage of a process for forming a film in accordance with one embodiment of the present invention.

### DETAILED DESCRIPTION

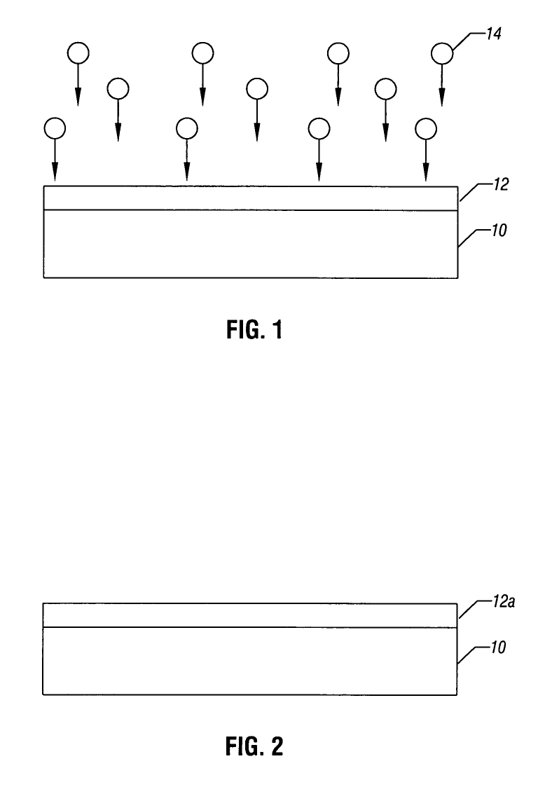

Referring to FIG. 1, a semiconductor substrate 10 may be any of the materials suitable to form semiconductor substrates, including silicon. In some cases, the substrate 10 may be a composite of different materials in addition to silicon or may use other materials not including silicon.

Deposited on the substrate 10 is a metallic film 12, such as a hafnium, zirconium, or tantalum containing film. The film 12 may be formed by the sputter deposition of metallic ions 14, such as hafnium or zirconium ions. In some embodiments, the film 12 may be formed by sputtering or physical vapor deposition. Any other material may be used for the film 12 so long as that material is stable in contact with the substrate 10. Hafnium, zirconium, and tantalum may be stable over silicon substrates.

Referring next to FIG. 2, the film 12 may be oxidized in the presence of a liquid oxidant to form an oxidized metallic film such as HfO₂, ZrO₂, or Ta₂O₅. In this case, an oxidizer, such as O₃, H₂O₂, or organic peroxide may be utilized in a solution. An aqueous solution may be utilized in some embodiments.

Because a liquid oxidant is utilized instead of a gas, the formation of an under layer may be reduced or eliminated. This reduces the controllability issues that arise when gaseous oxygen is used to form the oxidized metallic dielectric film.

By using physical vapor deposition in some embodiments, the purity of the film 12 may be very high, reducing the need for subsequent cleans and re-oxidations. Moreover, the oxidation of the metallic film 12 with aqueous solutions forms a near stoichiometric dielectric layer. Since the film 12 may be prepared from high purity precursors and need not involve ligand substitution, it may be very pure and it may be near idealized metal:oxygen stoichiometry. With ligand substitution techniques, such as HfCl₄ utilized in chemical vapor deposition, impurity problems may arise.

The resulting binary high dielectric film may be utilized in a variety of applications. One application is in connection with the formation of gate dielectric material. However, the present invention may be applied to any situation that involves the need for a high dielectric constant material. In some embodiments, ZrO₂ may have a dielectric constant of 25 and HfO₂ may have a dielectric constant as high as 40.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
forming a metal oxide dielectric using a liquid oxidizer.

2. The method of claim 1 including forming a metal oxide dielectric over a silicon substrate.

3. The method of claim 2 including forming the metal oxide dielectric of hafnium, zirconium, or tantalum.

4. The method of claim 1 wherein forming a metal oxide dielectric includes using physical vapor deposition to deposit metal atoms.

5. The method of claim 1 including using a liquid oxidizer selected from the group including solutions of O₃, H₂O₂ and organic peroxide.

6. The method of claim 1 wherein using a liquid oxidizer includes using an oxidizer in an aqueous solution.

7. A method comprising:
forming a dielectric using a metallic precursor; and
oxidizing said metallic precursor in a liquid.

8. The method of claim 7 including using a liquid oxidizer.

9. The method of claim 7 using an oxidizer in an aqueous solution.

10. The method of claim 7 including forming a metal oxide dielectric over a silicon substrate.

11. The method of claim 10 including forming a metal oxide dielectric of hafnium, zirconium, or tantalum.

12. The method of claim 7 including depositing a metallic film using physical vapor deposition.

13. The method of claim 7 including oxidizing using a liquid oxidizer selected from the group including solutions of O₃, H₂₀₂, and organic peroxide.

14. A method comprising:
forming a dielectric using a metal precursor; and
oxidizing said metallic precursor in a liquid without forming an oxidized layer under the metallic precursor.

15. The method of claim 14 including using a liquid oxidizer.

16. The method of claim 14 using an oxidizer in an aqueous solution.

17. The method of claim 14 including forming a metal oxide dielectric over a silicon substrate.

18. The method of claim 17 including forming a metal oxide dielectric of hafnium, zirconium, or tantalum.

19. The method of claim 14 including depositing a metallic film using physical vapor deposition.

20. The method of claim 14 including oxidizing using a liquid oxidizer selected from the group including solutions of O₃, H₂₀₂, and organic peroxide.

21-26. (Canceled).
